(19) United States
(12) Patent Application Publication
(10) Pub. No.: US 2024/0021615 A1
(43) Pub. Date: Jan. 18, 2024

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Yoonjeong KIM, Suwon-si (KR); Yeongmin JEON, Suwon-si (KR); Hyewon JANG, Suwon-si (KR)

(21) Appl. No.: 18/163,573

(22) Filed: Feb. 2, 2023

(30) Foreign Application Priority Data
Jul. 12, 2022 (KR) 10-2022-0085550

(51) Int. Cl. H01L 27/092; H01L 29/06; H01L 29/417; H01L 29/423; H01L 29/775; H01L 21/8238; H01L 29/66

(52) U.S. Cl. CPC H01L 27/092; H01L 29/0673; H01L 29/41733; H01L 29/42392; H01L 29/775; H01L 21/823807; H01L 21/823814; H01L 29/66545; H01L 29/66439

(57) ABSTRACT

A semiconductor device having active regions including a first active region and a second active region parallel to each other and respectively extending on a substrate in a first horizontal direction, a field region defining the active regions, a first insulating structure extending in the first horizontal direction on the field region, a gate structure extending, in a second horizontal direction, to intersect the active regions and the first insulating structure, source/drain regions disposed on at least one side of the gate structure, the source/drain regions including first source/drain regions on the first active region and second source/drain regions on the second active region, and a common contact plug on a first side of the gate structure and connected to the first and second source/drain regions opposing each other. The first insulating structure includes a first portion overlapping the gate structure in a vertical direction.

### CROSS-REFERENCE TO RELATED APPLICATION(S)

This application claims benefit of priority to Korean Patent Application No. 10-2022-0085550 filed on Jul. 12, 2022 in the Korean Intellectual Property Office, the disclosure of which is incorporated herein by reference in its entirety.

### BACKGROUND

The present disclosure relates to semiconductor devices and methods of manufacturing the semiconductor devices.

As demand for implementation of high performance, high speed, and/or multifunctionalization of semiconductor devices increases, a degree of integration of semiconductor devices may increase. In manufacturing semiconductor devices having a fine pattern corresponding to the trend for a high degree of integration of semiconductor devices, patterns having a fine width or a fine separation distance may be used. In addition, in order to overcome the limitation of operating properties due to the size reduction of a planar metal oxide semiconductor FET (MOSFET), efforts have been made to develop semiconductor devices including a FinFET with a three-dimensional channel structure.

### SUMMARY

An aspect of the present disclosure provides a semiconductor device having improved yield.

According to an aspect of the present disclosure, there is provided a semiconductor device having active regions including a first active region and a second active region parallel to each other and respectively extending on a substrate in a first horizontal direction, a field region defining the active regions on the substrate, a first insulating structure extending in the first horizontal direction on the field region between the first active region and the second active region, a gate structure extending, in a second horizontal direction, to intersect the active regions and the first insulating structure on the substrate, source/drain regions disposed on at least one side of the gate structure, the source/drain regions including a first source/drain region disposed on the first active region and a second source/drain region on the second active region, and a common contact plug disposed on a first side of the gate structure and electrically connected to the first and second source/drain regions opposing each other in the second horizontal direction. The first insulating structure may include a first portion overlapping the gate structure in a vertical direction, perpendicular to the first and second horizontal directions, and a second portion other than the first portion. At least a portion of the second portion of the first insulating structure may overlap the common contact plug in the vertical direction.

According to another aspect of the present disclosure, there is provided a semiconductor device including active regions extending on a substrate in a first horizontal direction, a field region defining the active regions, an insulating structure extending parallel to the active regions on the field region, insulating liners extending on side surfaces of the insulating structure in the first horizontal direction, a gate structure extending, in a second horizontal direction, to intersect the active regions and the insulating structure on the substrate, and source/drain regions disposed on the active regions and on at least one side of the gate structure. The insulating structure may have a first portion overlapping the gate structure in a vertical direction, perpendicular to the first and second horizontal directions, and a second portion other than the first portion. A first thickness of each of the insulating liners on a side surface of the first portion of the insulating structure may be less than a second thickness of each of the insulating liners on a side surface of the second portion of the insulating structure.

According to another aspect of the present disclosure, there is provided a semiconductor device including a first active region and a second active region parallel to each other and respectively extending on a substrate in a first horizontal direction, first, second, and third field regions defining the first and second active regions and spaced apart by the first and second active regions, a first insulating structure extending in the first horizontal direction on the second field region between the first active region and the second active region, a second insulating structure extending parallel to the first insulating structure on the first field region or the third field region, insulating liners extending in the first horizontal direction on side surfaces of each of the first and second insulating structures, gate structures including first and second gate structures extending, in a second horizontal direction, to intersect the first and second active regions and the first and second insulating structures on the substrate, the first and second gate structures opposing each other in the second horizontal direction, source/drain regions including first source/drain regions disposed on at least one side of the gate structures and disposed on the first active region and second source/drain regions disposed on the second active region, a common contact plug electrically connected to the first source/drain regions and second source/drain regions, and a gate isolation pattern disposed between the first and second gate structures on the second insulating structure. Each of the gate structures may include a gate electrode extending in the second horizontal direction and a gate spacer disposed on at least one side surface of the gate electrode. The insulating liners and the gate spacer may include a same material.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to example embodiments;

FIGS. 2A to 2E are cross-sectional views illustrating semiconductor devices according to example embodiments;

FIG. 3 is a cross-sectional view illustrating a semiconductor device according to example embodiments;

FIG. 4 is a cross-sectional view illustrating a semiconductor device according to example embodiments;

FIG. 5 is a cross-sectional view illustrating a semiconductor device according to example embodiments;

FIG. 6 is a cross-sectional view illustrating a semiconductor device according to example embodiments;

FIGS. 7A and 7B are cross-sectional views illustrating a semiconductor device according to example embodiments;

FIG. 8 is a cross-sectional view illustrating a semiconductor device according to example embodiments;

FIG. 9 is a plan view illustrating a semiconductor device according to example embodiments;

FIG. 10 is a cross-sectional view illustrating a semiconductor device according to example embodiments; and

FIGS. 11 to 23B are views illustrating sequential processes of a method of manufacturing a semiconductor device according to example embodiments.

### DETAILED DESCRIPTION

Hereinafter, example embodiments will be described with reference to the accompanying drawings.

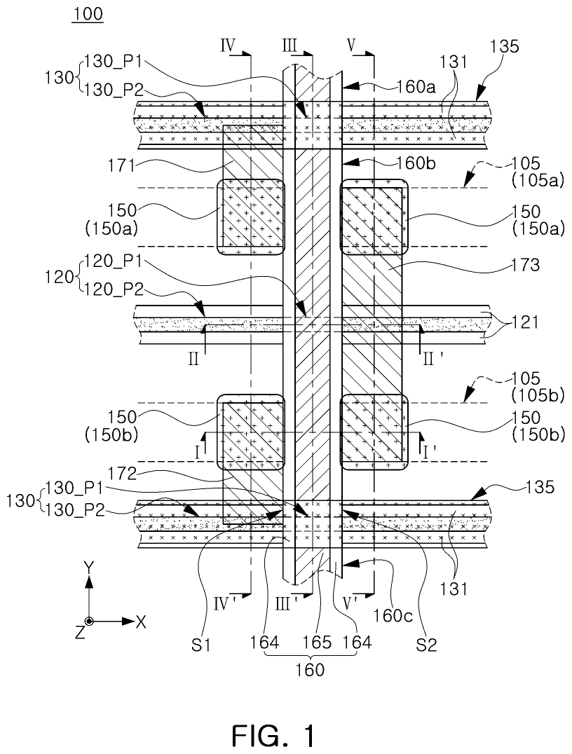

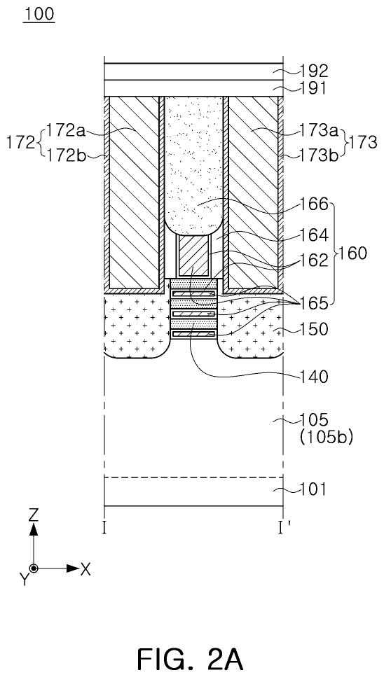

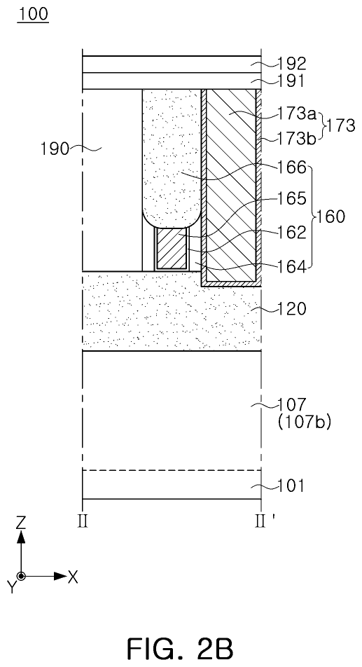

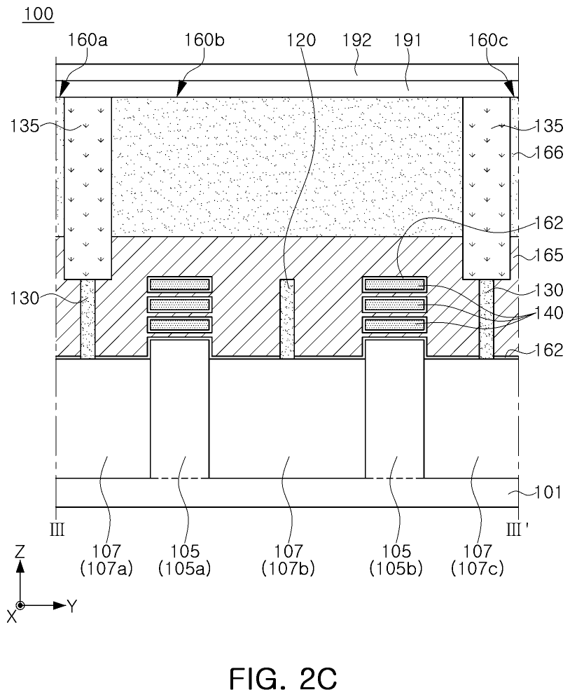

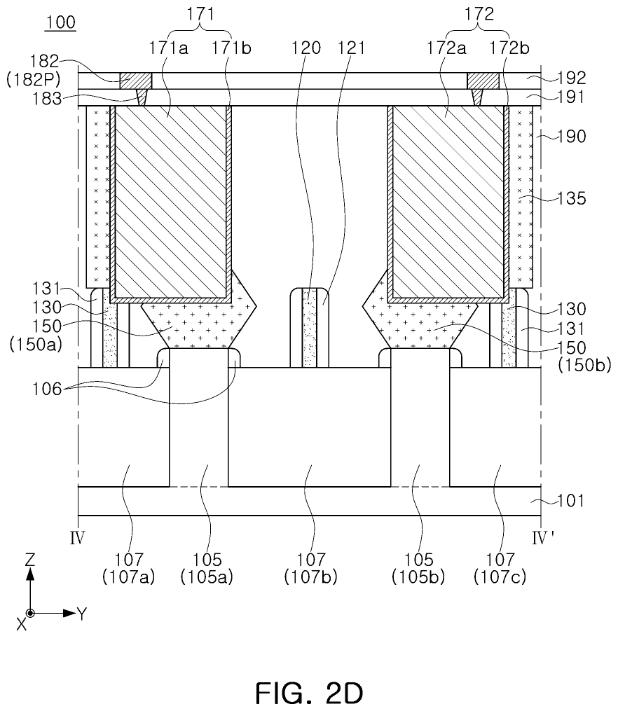

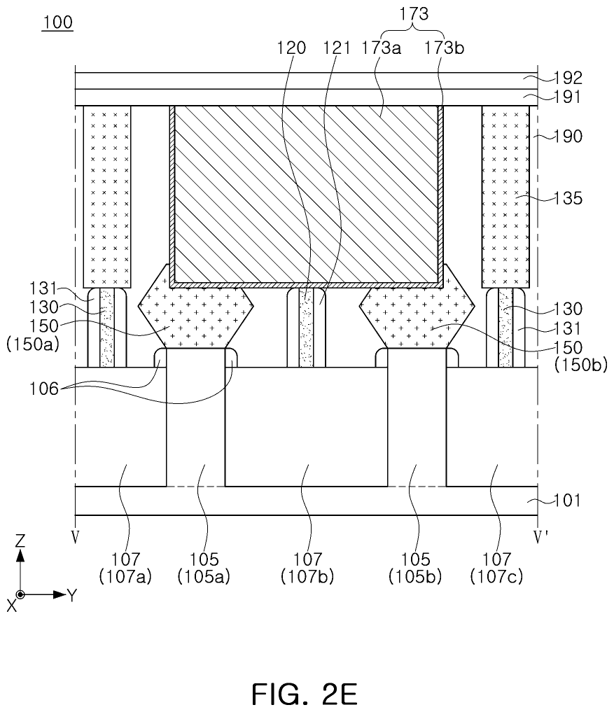

FIG. 1 is a plan view illustrating a semiconductor device 100 according to example embodiments. FIGS. 2A to 2E are cross-sectional views illustrating the semiconductor device 100 according to example embodiments. FIG. 2A illustrates a cross-section of the semiconductor device 100 of FIG. 1 taken along cutting line I-I′. FIG. 2B illustrates a cross-section of the semiconductor device 100 of FIG. 1 taken along cutting line FIG. 2C illustrates a cross-section of the semiconductor device 100 of FIG. 1 taken along cutting line FIG. 2D illustrates the semiconductor device 100 of FIG. 1 taken along cutting line IV-IV′. FIG. 2E illustrates a cross-section of the semiconductor device 100 of FIG. 1 taken along cutting line V-V. For ease of description, only major components of the semiconductor device 100 are illustrated in FIGS. 1 to 2E.

Referring to FIGS. 1 to 2E, the semiconductor device 100 may include a substrate 101, active regions 105 on the substrate 101, field regions 107 defining the active regions 105, first and second insulating structures 120 and 130 on the field regions 107, channel layers 140 disposed on the active regions 105, source/drain regions 150 on the channel layers 140, gate structures 160 extending to intersect the active regions 105, contact plugs 170, wiring lines 182, wiring vias 183, and an interlayer insulating layer 190. The gate structures 160 may include a gate dielectric layer 162, a gate electrode 165, gate spacers 164, and a gate capping layer 166. In an example embodiment, the semiconductor device 100 may further include gate isolation patterns 135.

In an example embodiment, the channel layers 140 may be vertically spaced apart from each other on the active regions 105. Accordingly, the active regions 105 may have a fin structure, and the gate electrode 165 may be disposed between the active regions 105 and a lowermost channel layer 140, between the channel layers 140, and on an uppermost channel layer 140. Accordingly, the semiconductor device 100 may be a transistor having a multi-bridge channel FET (MBCFET™) structure, a gate-all-around type field effect transistor formed by the channel layers 140, the source/drain regions 150, and the gate structures 160.

The substrate 101 may have an upper surface extending in an X-direction and a Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, a semiconductor on insulator (SeOI) layer, or the like.

The active regions 105 may be disposed to extend in a direction, parallel to the upper surface of the substrate 101, for example, the X-direction. The active regions 105 may be spaced apart from each other in the Y-direction, and may be disposed parallel to each other. The active regions 105 may protrude from the upper surface of the substrate 101 in a vertical Z-direction. Upper end portions of the active regions 105 may be disposed to protrude from the upper surface of the substrate 101 higher than upper end portions of the field regions 107 by a predetermined height. The active regions 105 may be formed as a portion of the substrate 101, or may include an epitaxial layer grown from the substrate 101. However, in side areas of the gate structures 160, the active regions 105 on the substrate 101 may be partially recessed, and the source/drain regions 150 may be disposed on the recessed active regions 105.

In an example embodiment, the active regions 105 may include a first active region 105a and a second active region 105b adjacent to each other. The first active region 105a and the second active region 105b may have a line shape or a bar shape extending in the X-direction, respectively. The first active region 105a and the second active region 105b may be spaced apart from each other and may extend parallel to each other, but the present disclosure is not limited thereto. The first active region 105a and the second active region 105b may have different conductivity types. When the first active region 105a has a first conductivity type, the second active region 105b may have a second conductivity type different from the first conductivity type. The first conductivity type may be an N-type conductivity type, and the second conductivity type may be a P-type conductivity type.

The field regions 107 may define the active regions 105 in the substrate 101. The field regions 107 may be disposed between the active regions 105. The upper end portions of the field regions 107 may be disposed on a level lower than those of the upper end portions of the active regions 105. Accordingly, the field regions 107 may partially expose upper portions of the active regions 105. In an example embodiment, the field regions 107 may have a curved upper surface having a higher level as a distance to the active regions 105 gradually decreases (e.g., convex shape toward the substrate 101), but the present disclosure is not limited thereto. The field regions 107 may be formed by, for example, a shallow trench isolation (STI) process. The field regions 107 may be filled with an insulating material. The insulating material may be, for example, an oxide, a nitride, or a combination thereof.

In an example embodiment, the field regions 107 may include first to third field regions 107a, 107b, and 107c spaced apart by the first and second active regions 105a and 105b. The first active region 105a may have an upper end portion protruding in the Z-direction between the first and second field regions 107a and 107b, and the second active region 105b may have an upper end portion protruding in the Z-direction between the second and third field regions 107b and 107c.

The insulating structures 120 and 130 may be disposed on the field regions 107. The insulating structures 120 and 130 may be disposed to extend on the field regions 107 in a direction, parallel to the active regions 105, for example, the X-direction. The insulating structures 120 and 130 may be spaced apart from each other in the Y-direction, and may be disposed parallel to each other. A width in the Y-direction of each of the insulating structures 120 and 130 may be in a range of about 5 nanometers (nm) to about 30 nm.

Lower surfaces of the insulating structures 120 and 130 may be positioned on a level lower than that of a lower surface of a lowermost channel layer among the channel layers 140 or those of lower surfaces of the source/drain regions 150. In an example embodiment, the insulating structures 120 and 130 may be in contact with the upper surfaces of the field regions 107. However, in some example embodiments, a lower end portion of each of the insulating structures 120 and 130 may extend into the field regions 107.

Upper surfaces of the insulating structures 120 and 130 may be positioned on a level lower than that of an upper surface of each of the gate structures 160 or that of an upper surface of each of the source/drain regions 150.

Each of the insulating structures 120 and 130 may include a nitride-based material, for example, at least one of SiN, SiON, SiCN, or SiOCN.

In an example embodiment, the insulating structures 120 and 130 may include the first insulating structure 120 and the second insulating structures 130 adjacent to each other. The first insulating structure 120 may extend in the X-direction on the field region 107 between the first active region 105a and the second active region 105b, for example, a second field region 107b. Each of the second insulating structures 130 may be spaced apart from the first insulating structure 120 and may extend parallel to the first insulating structure 120 on the field regions 107. Each of the second insulating structures 130 may be disposed on, for example, a first field region 107a or a third field region 107c. The first and second insulating structures 120 and 130 may include the same material, and may respectively have upper surfaces having substantially the same level.

The channel layers 140 may be disposed on the active regions 105 to be spaced apart from each other in the Z-direction, perpendicular to the substrate 101. The channel layers 140 may be spaced apart from upper surfaces of the active regions 105 while being connected to the source/drain regions 150. The channel layers 140 may have a width the same as or similar to those of the active regions 105 in the Y-direction, and may have a width the same as or similar to those of the gate structures 160 in the X-direction. However, in some example embodiments, the channel layers 140 may have a reduced width such that side surfaces thereof are positioned below the gate structures 160 in the X-direction. It is illustrated that the channel layers 140 include three channel layers, but the number of channel layers is not limited thereto and may be changed in various manners. For example, in some example embodiments, the channel layers 140 may further include additional channel layers disposed on the upper surfaces of the active regions 105. The channel layers 140 may be formed of a semiconductor material, and may include, for example, at least one of silicon (Si), silicon germanium (SiGe), and germanium (Ge). The channel layers 140 may include the same material, but may include different materials in some example embodiments.

The source/drain regions 150 may be disposed on the active regions 105 on at least one side of the channel layers 140. The source/drain regions 150 may be disposed to cover a side surface of each of the channel layers 140 and the upper surfaces of the active regions 105 at lower ends of the source/drain regions 150. The source/drain regions 150 may be in contact with the channel layers 140. The source/drain regions 150 may be disposed by partially recessing upper portions of the active regions 105. However, in some example embodiments, presence or absence of a recess and a depth of the recess may be changed in various manners. The source/drain regions 150 may be a semiconductor layer including silicon (Si), and may be formed of an epitaxial layer.

In an example embodiment, the source/drain regions 150 may include first source/drain regions 150a disposed on the first active region 105a and second source/drain regions 150b disposed on the second active region 105b. The first and second source/drain regions 105a and 105b may include different types of impurities and/or impurities having different concentrations. For example, the first source/drain regions 150a may have the second conductivity type (e.g., P-type conductivity type), and the second source/drain regions 150b may have the first conductivity type (e.g., N-type conductivity type). That is, the first source/drain regions 150a and the first active region 105a may have different conductivity types.

The first insulating structure 120 may be disposed between the first and second source/drain regions 150a and 150b opposing each other in the Y-direction on one side of the gate structures 160, for example, a second side S2. In an example embodiment, the first insulating structure 120 may be disposed to be spaced apart from the first and second source/drain regions 150a and 150b, but the present disclosure is not limited thereto. The first insulating structure 120 may be formed through a process prior to forming the source/drain regions 150, thereby preventing leakage current caused by the adjacent first and second source/drain regions 150a and 150b being in contact with each other through an epitaxial process. Accordingly, the semiconductor device 100 having improved productivity may be provided.

An upper surface of the first insulating structure 120 may be positioned on a level higher than levels of the lower surfaces of the source/drain regions 150 or a level on which the source/drain regions 150 have a maximum width.

The gate structures 160 may be disposed to intersect the active regions 105 and the channel layers 140 on upper portions of the active regions 105 and the channel layers 140 to extend in a direction, for example, the Y-direction. Channel regions of transistors may be formed in the active regions 105 and/or the channel layers 140 intersecting the gate structures 160.

Each of the gate structures 160 may include a gate dielectric layer 162, a gate electrode 165, a gate spacer 164, and a gate capping layer 166. An upper surface and a lower surface of each of the gate structures 160 between the channel layers 140 may be in contact with the plurality of channel layers 140.

The gate dielectric layer 162 may be disposed between each of the active regions 105 and the gate electrode 165 and between the channel layers 140 and the gate electrode 165, and may be disposed to cover at least portion of surfaces of the gate electrode 165. For example, the gate dielectric layer 162 may be disposed to surround all surfaces except an uppermost surface of the gate electrode 165. The gate dielectric layer 162 may extend between the gate electrode 165 and the gate spacer 164, but the present disclosure is not limited thereto. The gate dielectric layer 162 may include an oxide, nitride, or high-κ material. The high-κ material may refer to a dielectric material having a dielectric constant higher than that of a silicon oxide layer (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some example embodiments, the gate dielectric layer 162 may be formed of multilayers.

The gate electrode 165 may be disposed on the active regions 105 to fill a space between the channel layers 140 and to extend to upper portions of the channel layers 140. The gate electrode 165 may be spaced apart from the channel layers 140 by the gate dielectric layer 162. The gate electrode 165 may include a conductive material, for example, a metal nitride such as a titanium nitride film (TiN), a tantalum nitride film (TaN), or a tungsten nitride film (WN), and/or a metallic material such as aluminum (Al), tungsten (W), or molybdenum (Mo) or a semiconductor material such as doped polysilicon. In some example embodiments, the gate electrode 165 may be formed of two or more multilayers. Depending on a configuration of the semiconductor device 100, the gate electrode 165 may be disposed to be isolated by an isolator between at least some of adjacent transistors. The gate electrode 165 may include different materials depending on transistor regions.

The gate spacers 164 may be disposed on sidewalls of the gate electrode 165 and may extend in the Z-direction, perpendicular to the upper surface of the substrate 101. The gate spacer 164 may include a portion having an upper portion having a width narrower than that of a lower portion. However, in some example embodiments, a shape of the gate spacer 164 may be changed in various manners. The gate spacer 164 may insulate the source/drain regions 150 and the gate electrode 165 from each other. In some example embodiments, the gate spacer 164 may be formed of multilayers. The gate spacer 164 may be formed of oxide, nitride, or oxynitride.

The gate capping layer 166 may be disposed on the gate electrode 165. The gate capping layer 166 may be a structure for protecting the gate electrode 165 from being etched in a subsequent process after the gate electrode 165 is formed, but a role of the gate capping layer 166 is not limited thereto. The gate capping layer 166 may be disposed on the gate electrode 165 and the gate spacer 164. At least a portion of a lower surface of the gate capping layer 166 may be surrounded by the gate electrode 165 and the gate spacer 164. In an example embodiment, the gate capping layer 166 may include a lower surface having a convex shape toward the substrate 101. The gate capping layer 166 may include silicon nitride or a silicon nitride-based insulating material.

In some example embodiments, the semiconductor device 100 may further include inner spacer layers disposed parallel to the gate electrode 165 between the channel layers 140. The gate electrode 165 positioned below an uppermost channel layer among the channel layers 140 may be spaced apart from the source/drain regions 150 by the inner spacer layers to be electrically isolated therefrom. The inner spacer layers may have a shape in which a side thereof opposing the gate electrode 165 is inwardly convex rounded shape toward the gate electrode 165, but the present disclosure is not limited thereto. The inner spacer layers may be formed of oxide, nitride, or oxynitride, and in particular, a low-κ film. In some example embodiments, the inner spacer layers may be omitted.

The gate structures 160 may extend in a direction to intersect the insulating structures 120 and 130 above the insulating structures 120 and 130. Each of the gate structures 160 may cover at least a portion of upper surfaces and side surfaces of the insulating structures 120 and 130.

An upper surface of each of the insulating structures 120 and 130 may be positioned on a level lower than that of an uppermost surface of each of the gate structures 160, and may be positioned on a level higher than that of a lowermost surface of each of the gate structures 160.

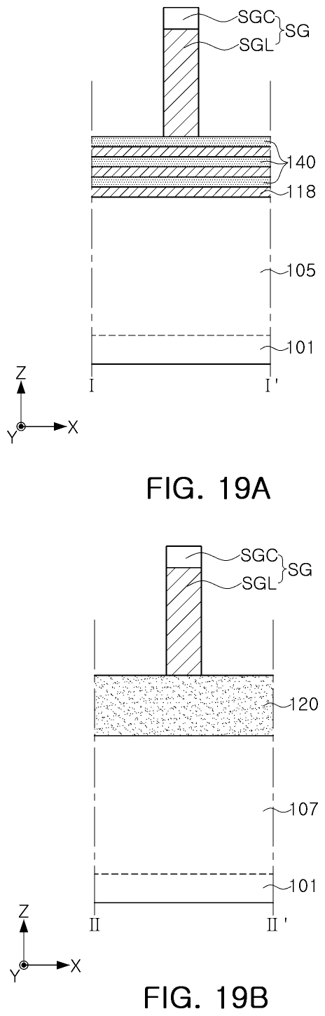

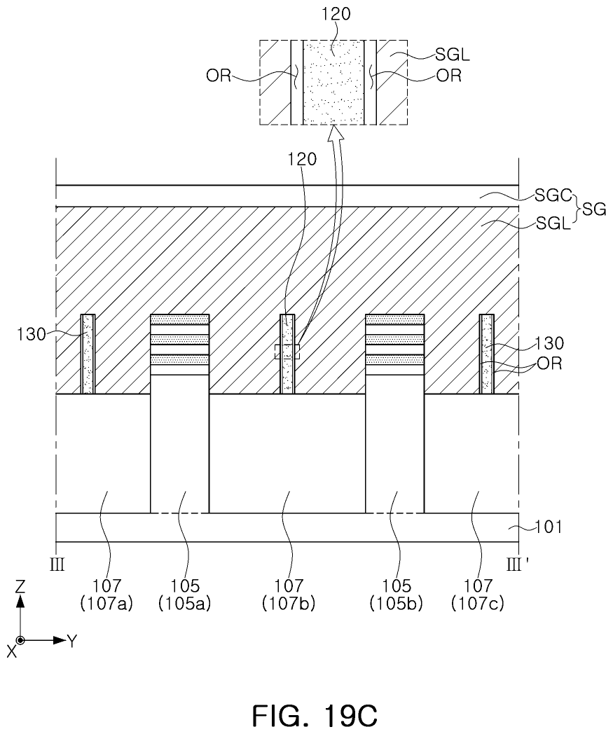

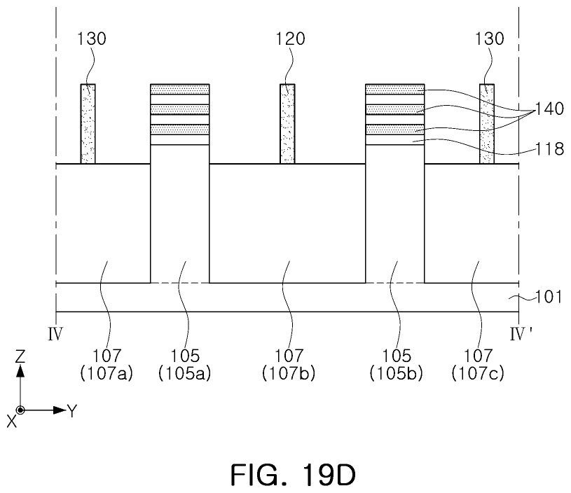

As the insulating structures 120 and 130 have a fin shape, the side surfaces and upper surfaces of the insulating structures 120 and 130 may be in contact with the gate structures 160, thereby improving a tilt phenomenon of the gate structures 160 or sacrificial gate structures SG (see FIG. 19A).

In an example embodiment, the gate structures 160 may include first to third gate structures 160a, 160b, and 160c isolated from each other in the Y-direction in which the gate structures 160 extend. The first to third gate structures 160a, 160b, and 160c may have substantially the same width in the X-direction. The first gate structure 160a and the second gate structure 160b may be physically disposed to be spaced apart from each other by the second insulating structures 130 and the gate isolation patterns 135, and may be electrically isolated from each other. Similarly, the second and third gate structures 160b and 160c may be physically disposed to be spaced apart from each other by the second insulating structures 130 and the gate isolation patterns 135, and may be electrically isolated from each other.

The gate isolation patterns 135 may be disposed on the field regions 107. In an example embodiment, each of the gate isolation patterns 135 may have a line shape extending in the X-direction in a plan view, but the present disclosure is not limited thereto, and may be a plurality of structures isolated from each other and spaced apart from each other.

The gate isolation patterns 135 may extend in the X-direction on the second insulating structures 130. Each of the gate isolation patterns 135 may cover at least a portion of an upper surface of each of the second insulating structures 130. The second insulating structures 130 may overlap the gate isolation patterns 135 in the Z-direction. In an example embodiment, a width in the Y-direction of each of the gate isolation patterns 135 may be wider than a width in the Y-direction of each of the second insulating structures 130.

The gate isolation patterns 135 may physically isolate the adjacent gate structures 160 while being in contact with at least one side of the gate structures 160. In an example embodiment, the gate isolation patterns 135 may include a first gate isolation pattern 135a isolating the first and second gate structures 160a and 160b from each other while being in contact with opposite side surfaces of the first and second gate structures 160a and 160b, and a second gate isolation pattern 135b isolating the second and third gate structures 160b and 160c from each other while being in contact with opposite side surfaces of the second and third gate structures 160b and 160c.

An upper surface of each of the gate isolation patterns 135 may be positioned on a level substantially the same as that of an upper surface of each of the gate structures 160, but may be positioned on a level higher than that of each of the gate structures 160 in some example embodiments.

The gate isolation patterns 135 may include a nitride-based material, for example, at least one of SiN, SiON, SiCN, or SiOCN. The gate isolation patterns 135 may include a material the same as that of the gate spacer 164, but the present disclosure is not limited thereto.

The contact plugs 170 may pass through the interlayer insulating layer 190 to be connected to the source/drain regions 150. The contact plugs 170 include a first contact plug 171 electrically connected to the first source/drain regions 150a, a second contact plug 172 electrically connected to the second source/drain regions 150b, and a common contact plug 173 electrically connected to the first and second source/drain regions 150a and 150b.

In an example embodiment, the first source/drain region 150a disposed on a first side S1 of the gate structure 160 may be electrically connected to the first contact plug 171. The second source/drain region 150b disposed on the first side S1 of the gate structure 160 may be electrically connected to the second contact plug 172. The first and second source/drain regions 150a and 150b disposed on the second side S2 opposite to the first side S1 of the gate structure 160 may be electrically connected to the common contact plug 173.

The first and second contact plugs 171 and 172 may pass through the interlayer insulating layer 190 to be respectively connected to the source/drain regions 150, and may apply an electrical signal to the source/drain regions 150. Each of the first and second contact plugs 171 and 172 may have an inclined side surface having a width decreasing in a direction toward the substrate 101 according to an aspect ratio, but the present disclosure is not limited thereto. The first and second contact plugs 171 and 172 may be recessed to a predetermined depth from the source drain regions 150, but the present disclosure is not limited thereto.

The common contact plug 173 may be in contact with the first and second source/drain regions 150a and 150b at the same time. The common contact plug 173 may have a line shape extending in the Y-direction. The common contact plug 173 may be in contact with upper surfaces of the first and second source/drain regions 150a and 150b and an upper surface of the first insulating structure 120.

The contact plugs 171, 172, and 173 may include plug layers 171a, 172a, and 173a and barrier layers 171b, 172b, and 173b. The plug layers 171a, 172a, and 173a may include, for example, a metal nitride such as a titanium nitride film (TiN), a tantalum nitride film (TaN), or a tungsten nitride film (WN), and/or a metal material such as aluminum (Al), tungsten (W), or molybdenum (Mo). The barrier layers 171b, 172b, and 173b may conformally cover side surfaces and bottom surfaces of the plug layers 171a, 172a, and 173a. The barrier layers 171b, 172b, and 173b may include, for example, a metal nitride such as a titanium nitride layer (TiN), a tantalum nitride layer (TaN), or a tungsten nitride layer (WN).

In an example embodiment, the first insulating structure 120 may not overlap the first and second contact plugs 171 and 172 in the Z-direction, and at least a portion of the second insulating structure 130 may overlap the first and second contact plugs 171 and 172 in the Z-direction.

The first insulating structure 120 may include a first portion 120_P1 overlapping the gate structure 160 in the Z-direction and a remaining second portion 120_P2. At least a portion of the second portion 120_P2 of the first insulating structure 120 may vertically overlap the common contact plug 173. The gate structures 160 may be in contact with at least a portion of an upper surface and a side surface of the first portion 120_P1 of the first insulating structure 120, and the common contact plug 173 may be in contact with an upper surface of the second portion 120_P2 of the first insulating structure 120. The common contact plug 173 having an improved recess defect (e.g., preventing a recess defect) by the first insulating structure 120 may be provided. The recess defect may refer to a defect occurring as a result of having a lower surface of the contact plug 173 at a lower level in a region between the first and second source/drain regions 150a and 150b than in a region where a lower surface of the contact plug 173 is in contact with the first and second source/drain regions 150a and 150b. The first insulating structure 120 may include a material having an etching rate lower than that of the interlayer insulating layer 190 under a specific etching condition, thereby preventing the recess defect during a contact hole etching operation for forming the common contact plug 173.

The second insulating structure 130 may include a first portion 130_P1 overlapping the gate structure 160 in the Z-direction and a remaining second portion 130_P2.

The semiconductor device 100 may further include insulating liners 121 and 131 extending in the X-direction on side surfaces of the insulating structures 120 and 130. In an example embodiment, the insulating liners 121 and 131 may include first insulating liners 121 extending in the X-direction on side surfaces of the second portion 120_P2 of the first insulating structure 120, and second insulating liners 131 extending in the X-direction on side surfaces of the second portion 130_P2 of the second insulating structure 130. In the present example embodiment, the first and second insulating liners 121 and 131 may be disposed only on side surfaces of the second portions 120_P2 and 130_P2 of the first and second insulating structures 120 and 130, and may not be disposed on side surfaces of the first portions 120_P1 and 130_P1 of the first and second insulating structures 120 and 130.

The insulating liners 121 and 131 may include a nitride-based material, for example, at least one of SiN, SiCN, SiON, or SiOCN. Each of the insulating liners 121 and 131 may have a thickness of about 5 nm to 30 nm in the Y-direction.

In an example embodiment, the insulating liners 121 and 131 may include a material the same as that of the gate spacers 164. Each of the insulating liners 121 and 131 may have a thickness substantially the same as that of each of the gate spacers 164. This may be because the insulating liners 121 and 131 are layers deposited simultaneously with material layer for forming the gate spacer 164.

In an example embodiment, the semiconductor device 100 may further include dummy insulating liners 106. When the upper end portions of the active regions 105 are disposed to protrude from the substrate 101 higher than the upper end portions of the field regions 107 by a predetermined height, the dummy insulating liners 106 may be disposed on side surfaces of the protruding active regions 105. The dummy insulating liners 106 may include a material the same as that of the gate spacers 164, and may have a thickness substantially equal to a thickness of each of the gate spacers 164 and/or a thickness of each of the insulating liners 121 and 131.

The interlayer insulating layer 190 may cover the source/drain regions 150 and the gate structures 160. The interlayer insulating layer 190 may cover the field regions 107 and the insulating structures 120 and 130. The interlayer insulating layer 190 may include, for example, at least one of an oxide, a nitride, and an oxynitride, and may include a low-κ material.

The semiconductor device 100 may further include first and second upper insulating layers 191 and 192 on the interlayer insulating layer 190.

The wiring lines 182 and the wiring vias 183 may form an upper wiring structure. The wiring lines 182 may be disposed on the interlayer insulating layer 190. The wiring lines 182 may be electrically connected to, for example, the contact plugs 171, 172, and 173. The wiring vias 183 may pass through a first upper insulating layer 191, and may electrically connect the wiring lines 182 and the contact plugs 171, 172, and 173 to each other. A second upper insulating layer 192 may cover side surfaces of the wiring lines 182, and may have an upper surface substantially coplanar with upper surfaces of the wiring lines 182.

In some example embodiments, the number of wiring lines included in an upper wiring structure may be changed in various manners. The wiring lines 182 and the wiring vias 183 may include metal, for example, tungsten (W), copper (Cu), aluminum (Al), or the like.

In an example embodiment, the wiring lines 182 may include power lines 182P extending in the X-direction. In a plan view, the first and second active regions 105a and 105b may be disposed between two adjacent power lines 182P. The power lines 182P may include a portion overlapping the gate isolation patterns 135 and/or the second insulating structures 130 in the Z-direction.

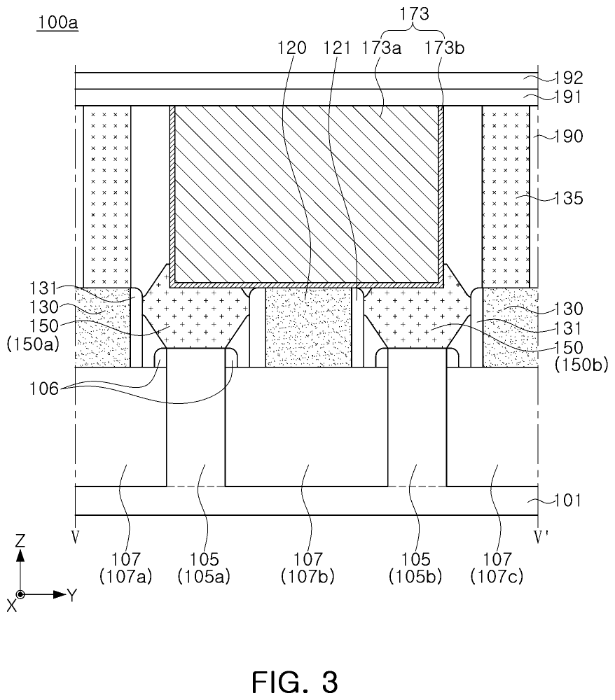

FIG. 3 is a cross-sectional view illustrating a semiconductor device according to example embodiments. FIG. 3 illustrates a region corresponding to a cross-section taken along cutting line V-V of FIG. 1.

Referring to FIG. 3, in a semiconductor device 100a according to example embodiments, the source/drain regions 150a and 150b may be in contact with the insulating liners 121 and 131. A portion of outer surfaces of the insulating liners 121 and 131 disposed on opposite sides of the insulating structures 120 and 130 may be in contact with the source/drain regions 150a and 150b.

This may be because the insulating structures 120 and 130 have a relatively wide width in a Y-direction, as compared to FIG. 2E. Alternatively, this may be because a distance between the adjacent active regions 105a and 105b becomes relatively narrower with a high degree of integration of a semiconductor device, or the source/drain regions 150a and 150b are formed to have a relatively large size depending on a process condition.

In an example embodiment, a portion of the source/drain regions 150a and 150b may include a portion extending or rounded along sidewalls of the insulating liners 121 and 131. This may be a structure according to the source/drain regions 150a and 150b being epitaxially grown after the insulating structures 120 and 130 and the insulating liners 121 and 131 are formed.

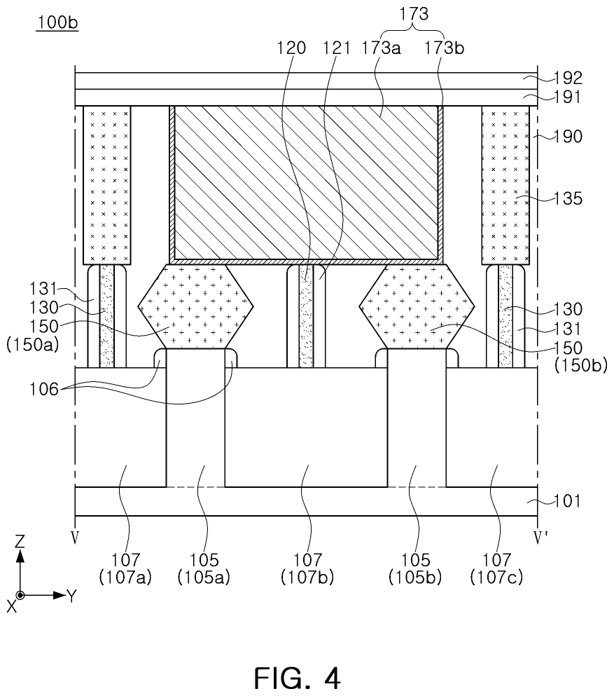

FIG. 4 is a cross-sectional view illustrating a semiconductor device according to example embodiments. FIG. 4 illustrates a region corresponding to a cross-section taken along cutting line V-V of FIG. 1.

Referring to FIG. 4, in a semiconductor device 100b according to example embodiments, upper surfaces of the insulating structures 120 and 130 may be positioned on a level higher than that of an uppermost channel layer among the channel layers 140 or positioned on a level substantially the same as that of uppermost surfaces of the source/drain regions 150a and 150b. In addition, in some example embodiments, the upper surfaces of the insulating structures 120 and 130 may be adjusted in various manners on a level lower than that of an upper surface of the gate structure 160. This may be because the insulating structures 120 and 130 are formed before a sacrificial gate structure SG (see FIG. 19A) is formed.

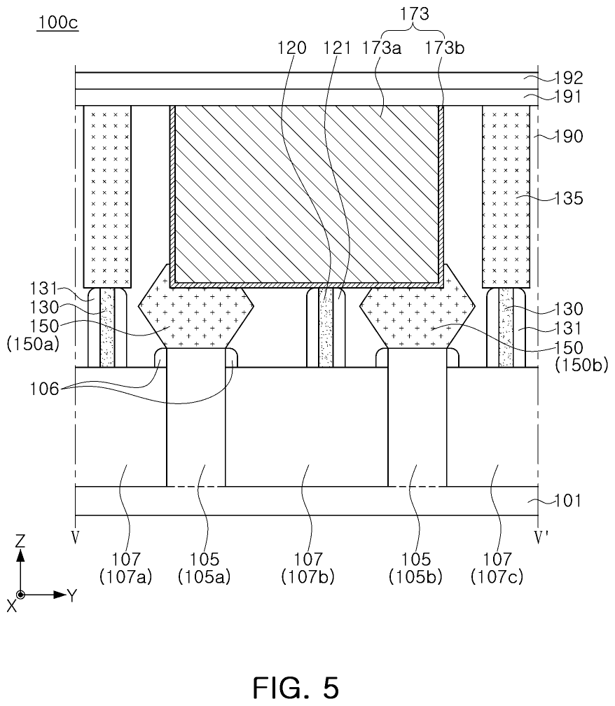

FIG. 5 is a cross-sectional view illustrating a semiconductor device according to example embodiments. FIG. 5 illustrates a region corresponding to a cross-section taken along cutting line V-V of FIG. 1.

Referring to FIG. 5, in a semiconductor device 100c according to example embodiments, a distance from the first insulating structure 120 to the first active region 105a may be different from a distance from the first insulating structure 120 to the second active region 105b. That is, the first insulating structure 120 may be disposed to be spaced apart from a central axis between the first and second active regions 105a and 105b by a predetermined distance. Accordingly, a distance from the first insulating structure 120 to first source/drain regions 150a may be different from a distance from the first insulating structure 120 to second source/drain regions 150b.

This may be because the insulating structures 120 and 130 are formed by an exposure process and an etching process using a mask instead of a self-aligning process.

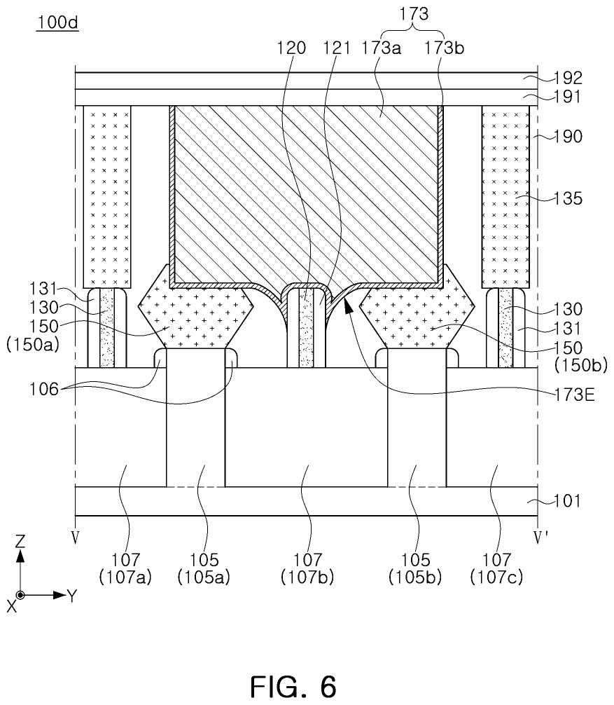

FIG. 6 is a cross-sectional view illustrating a semiconductor device according to example embodiments. FIG. 6 illustrates a region corresponding to a cross-section taken along cutting line V-V′ of FIG. 1.

Referring to FIG. 6, in a semiconductor device 100d according to the example embodiments, the common contact plug 173 may have an extension portion 173E extending onto a side surface of the first insulating structure 120 while covering an upper surface of the first insulating structure 120. In an example embodiment, the extension portion 173E of the common contact plug 173 may be in contact with at least a portion of side surfaces of the insulating liners 121 disposed on side surfaces of the first insulating structure 120. Accordingly, a lower end of the common contact plug 173 may be positioned at a level lower than that of the upper surface of the first insulating structure 120.

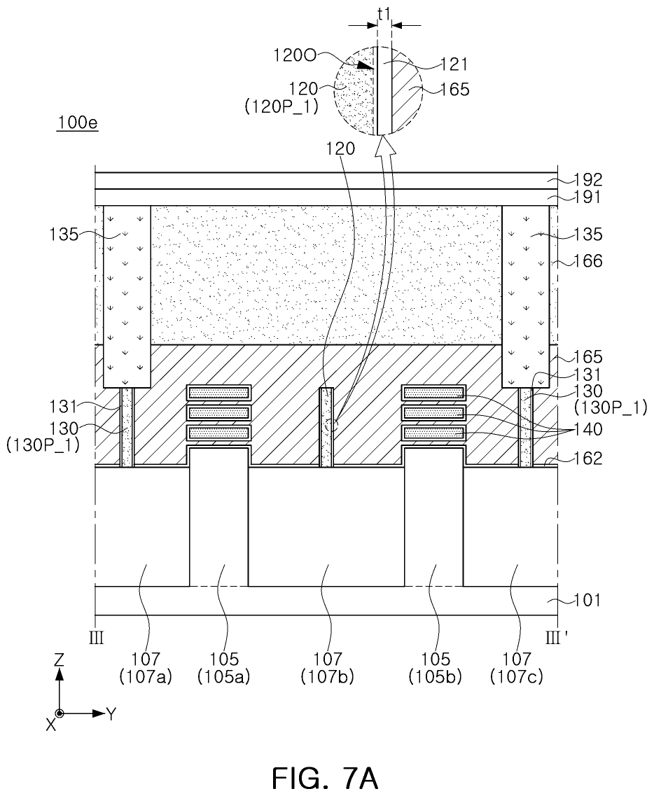

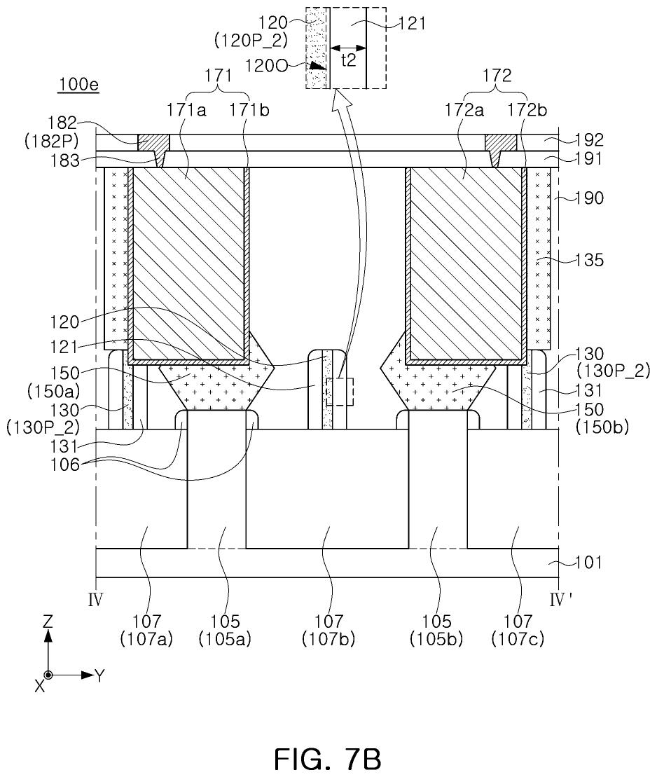

FIGS. 7A and 7B are cross-sectional views illustrating a semiconductor device according to example embodiments. FIG. 7A illustrates a region corresponding to a cross-section taken along cutting line III-III′ of FIG. 1, and FIG. 7B illustrates a region corresponding to a cross-section taken along cutting line IV-IV′ of FIG. 1.

Referring to FIGS. 7A and 7B, a semiconductor device 100e according to example embodiments may have insulating structures 120 and 130 and insulating liners 121 and 131 different from those of FIGS. 2A to 2E.

The insulating structures 120 and 130 may have the first portions 120_P1 and 130_P1 overlapping the gate structure 160 in a Z-direction and the second portions 120_P2 and 130_P2.

Unlike the insulating liners of the semiconductor device 100 of FIGS. 2A to 2E, the first insulating liners 121 may also be disposed on a side surface of the first portion 120_P1. That is, the first insulating liners 121 may be connected to and extend on side surfaces of the first and second portions 120P_1 and 120P_2 of the first insulating structure 120.

In an example embodiment, a first thickness t1 of each of the first insulating liners 121 on the side surface of the first portion 120P_1 may be less than a second thickness t2 of each of the first insulating liners 121 on the side surface of the second portion 120P_2. The second thickness t2 may be substantially the same as or similar to a thickness of the gate spacer 164, and the first thickness t1 may be less than the thickness of the gate spacer 164. For example, the first thickness t1 may be in a range of about 1 nm to about 10 nm, and the second thickness t2 may be in a range of about 5 nm to about 30 nm.

The second insulating liners 131 may have features the same as or similar to those described with respect to the first insulating liners 121.

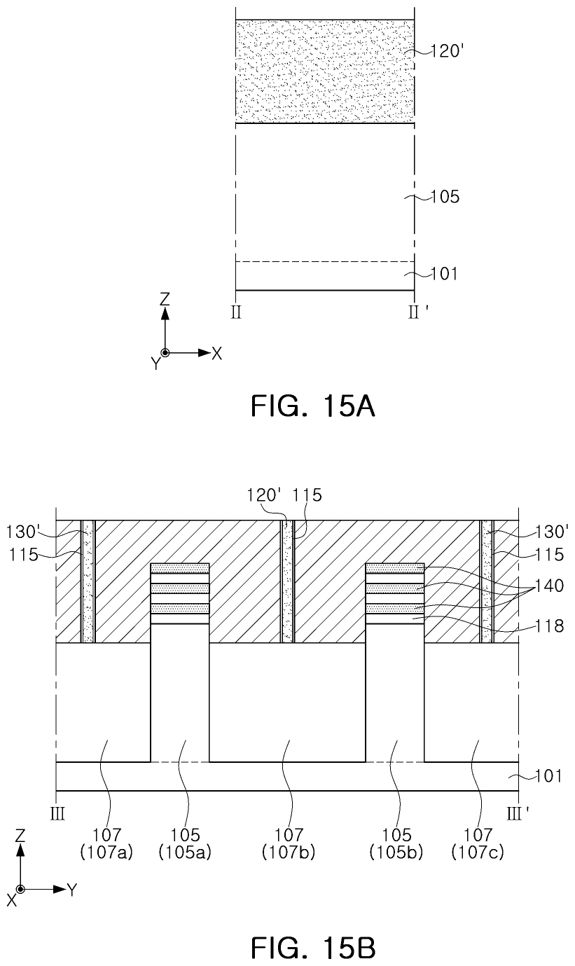

In an example embodiment, the insulating structures 120 and 130 may be in contact with the insulating liners 121 and 131, and may have outer regions 120O and 130O adjacent to portions in contact with the insulating liners 121 and 131. The outer regions 120O and 130O may include germanium (Ge) or germanium (Ge)-based impurities. This may be because semiconductor liners 115 including a germanium element are used in a process of forming the insulating structures 120 and 130, referring to FIGS. 15A and 15B together. A semiconductor element in the semiconductor liners 115 may be diffused into a portion of the insulating structures 120 and 130 through a subsequent process to form the outer regions 120O and 130O.

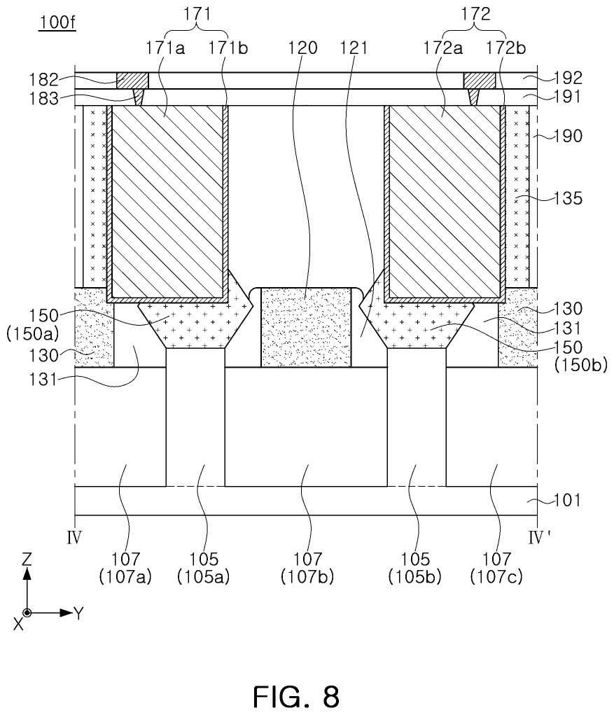

FIG. 8 is a cross-sectional view illustrating a semiconductor device according to example embodiments. FIG. 8 illustrates a region corresponding to a cross-section taken along cutting line IV-IV′ of FIG. 1.

Referring to FIG. 8, in a semiconductor device 100f according to example embodiments, the insulating liners 121 and 131 may cover upper surfaces of the field regions 107. The insulating liners 121 and 131 may include a material the same as that of the gate spacer 164, but may have a thickness different from that of the gate spacer 164.

This may be because a folding phenomenon of the insulating liners 121 and 131 occurs in a process of forming the insulating liners 121 and 131 as a distance between the insulating structures 120 and 130 and the source/drain regions 150a and 150b becomes relatively narrow. The folding phenomenon may occur as a portion of an insulating layer is not removed and remains while forming the insulating layer and performing an anisotropic etching process.

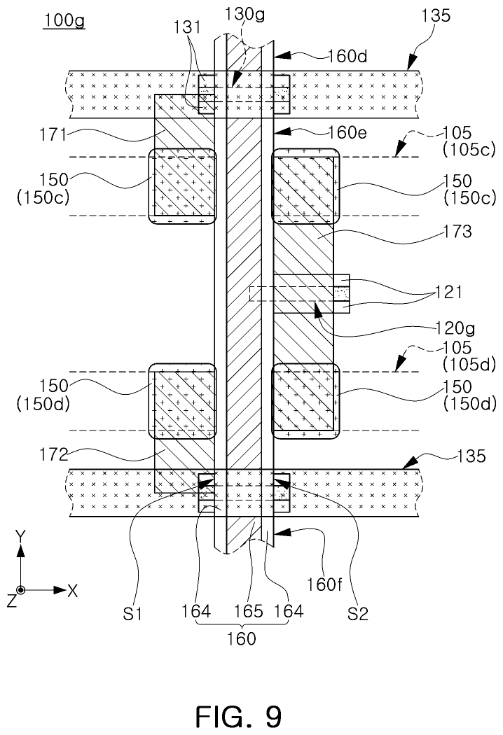

FIG. 9 is a plan view illustrating a semiconductor device according to example embodiments.

Referring to FIG. 9, a semiconductor device 100g according to example embodiments may further include third and fourth active regions 105c and 105d on the substrate 101, a third insulating structure 120g and fourth insulating structures 130g on the field regions 107, and third and fourth source/drain regions 150c and 150d on the third and fourth active regions 105c and 105d.

The third and fourth active regions 105c and 105d may be active regions spaced apart from the first and second active regions 105a and 105b and extending parallel to each other in an X-direction.

The third source/drain regions 150c may be disposed on the third active region 105c, and the fourth source/drain regions 150d may be disposed on the fourth active region 105d.

The third insulating structure 120g may be disposed between the third and fourth source/drain regions 150c and 150d opposing each other. The third insulating structure 120g may be in contact with a common contact plug 173 electrically connected to the third and fourth source/drain regions 150c and 150d. The third insulating structure 120g may have an upper surface having a level substantially the same as those of upper surfaces of the insulating structures 120 and 130 of FIGS. 1 to 2E. Unlike the insulating structures 120 and 130 of FIGS. 1 to 2E, the third insulating structure 120g may be a hole-type structure in a plan view. In the example embodiment, it is illustrated that the third insulating structure 120g is in the form of a hole with angled edges, but may have various shapes, such as a polygon, an ellipse, or a circle with rounded edges. The third insulating structure 120g may be disposed to overlap at least a portion of the gate structure 160 in a Z-direction. Alternatively, the third insulating structure 120g may not overlap the gate structure 160.

The fourth insulating structure 130g may be disposed to overlap the gate isolation pattern 135 in the Z-direction. The fourth insulating structure 130g may be a hole-type structure in the same manner as the third insulating structure 120g. The fourth insulating structure 130g may serve to physically isolate the adjacent gate structures 160 from each other, together with the gate isolation pattern 135.

In the present example embodiment, it is described that the semiconductor device 100g includes the third and fourth insulating structures 120g and 130g together with the first and second insulating structures 120 and 130. However, in some example embodiments, the semiconductor device 100g may not include the first and second insulating structures 120 and 130, but may include at least one of the third and fourth insulating structures 120g and 130g.

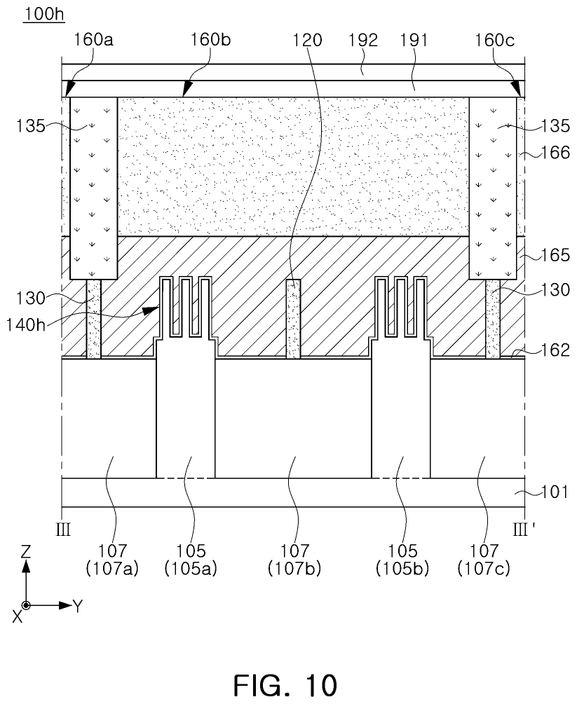

FIG. 10 is a cross-sectional view illustrating a semiconductor device according to example embodiments. FIG. 10 illustrates a region corresponding to a cross-section taken along cutting line III-III′ of FIG. 1.

Referring to FIG. 10, in a semiconductor device 100h according to example embodiments, a plurality of fin structures 140h instead of channel layers disposed vertically spaced apart from each other may form a channel structure. The plurality of fin structures 140h may have a fin structure extending from the active regions 105 in a Z-direction. In the present example embodiment, it is illustrated that the number of the plurality of fin structures 140h disposed on an upper surface of each of the active regions 105 is three, but the number of the plurality of fin structures 140h is not limited thereto, and may be changed in various manners.

Accordingly, the semiconductor device 100h may be a fin-type field effect transistor formed by the plurality of fin structures 140h, the source/drain regions 150 (see FIGS. 2A to 2E), and the gate structure 160.

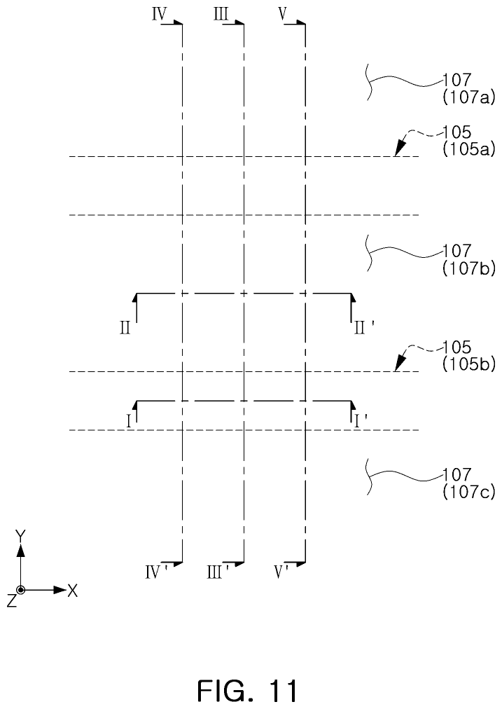

FIGS. 11 to 23B are views illustrating sequential processes of a method of manufacturing a semiconductor device according to example embodiments. FIGS. 11 to 23B illustrate an example embodiment of a method for manufacturing the semiconductor device 100 of FIGS. 1 to 2E or the semiconductor device 100e of FIGS. 7A to 7B.

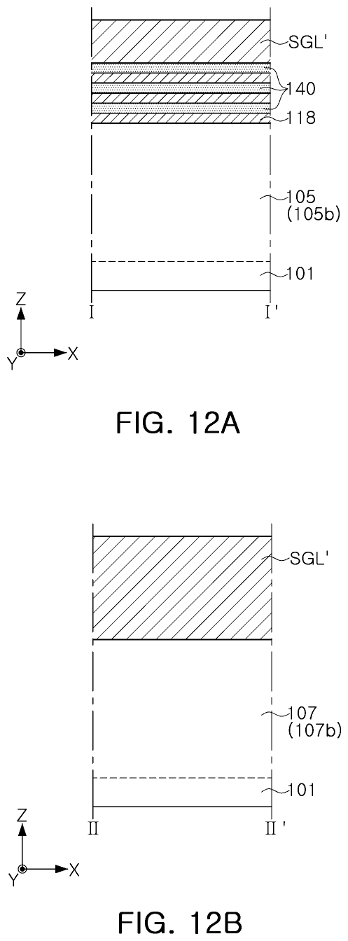

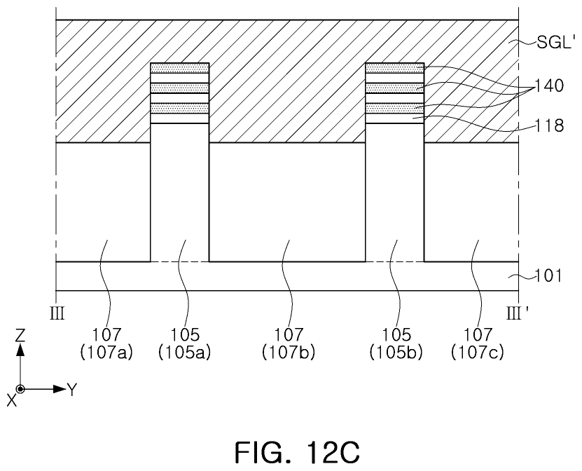

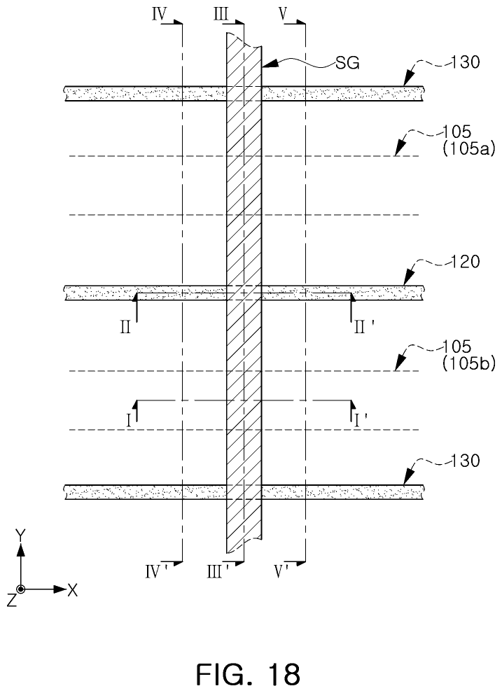

FIGS. 11, 13, 18, 20, and 22 are plan views sequentially illustrating a method of manufacturing a semiconductor device according to example embodiments of the present disclosure. FIGS. 12A, 19A, 21A, and FIG. 23A are cross-sectional views illustrating a region taken along line I-I′ of FIGS. 11, 13, 18, and 20. FIGS. 12B, 14A, 15A, 16A, 17A, 19B, and 21B are cross-sectional views illustrating a region taken along line II-II′ of FIGS. 11, 13, 18, and 20. FIGS. 12C, 14B, 15B, 16B, 17B, 19C, and 21C are cross-sectional views taken along line III-III′ of FIGS. 11, 13, 18, and 20. FIGS. 19D, 21D, and 23B are cross-sectional views taken along line Iv-IV of FIGS. 18, 20, and 22.

Referring to FIGS. 11, 12A, 12B, and 12C, active structures (including active regions 105, sacrificial layers 118, and channel layers 140) may be formed on a substrate 101, and a portion of a preliminary sacrificial gate layer SGL′ may be formed.

Sacrificial layers 118 and channel layers 140 may be formed to be alternately stacked on the substrate 101, and the alternately stacked sacrificial layers 118 and channel layers 140, and at least a portion of the substrate 101 may be etched to form a trench defining the active regions 105, thereby forming the active structures 105, 118, and 140. The active structures 105, 118, and 140 may include the active regions 105, and the sacrificial layers 118 and channel layers 140 alternately stacked on the active regions 105.

The sacrificial layers 118 and the channel layers 140 may be formed by an epitaxial growth process. The sacrificial layers 118 may be layers replaced by the gate dielectric layer 162 and the gate electrode 165 through a subsequent process, as illustrated in FIG. 2A. The sacrificial layers 118 may be formed of a material having etch selectivity with respect to the channel layers 140. The sacrificial layers 118 and the channel layers 140 may include, for example, a semiconductor material including at least one of silicon (Si), silicon germanium (SiGe), and germanium (Ge), and may include different materials. The sacrificial layers 118 may include, for example, silicon germanium (SiGe), and the channel layers 140 may include silicon (Si). In an example embodiment, the channel layers 140 may be formed by stacking three layers having substantially the same thickness, but the present disclosure is not limited thereto and the number and thickness of the channel layers may be changed in various manners in some example embodiments.

The active regions 105 may be regions defined by the trench. The active regions 105 may be regions formed to protrude from an upper surface of the substrate 101 by removing a portion of the substrate 101. The active regions 105 may have a shape protruding from the substrate 101 in a Z-direction, perpendicular to the substrate 101, and may be formed of a material as that of the substrate 101. The active regions 105 may have a line shape extending in a direction, for example, an X-direction, and may be disposed to be spaced apart from each other in a Y-direction.

In an example embodiment, the active structures 105, 118, and 140 may include a first active structure and a second active structure spaced apart from each other in the Y-direction. The first active structure may include a first active region 105a, first sacrificial layers and first channel layers alternately stacked on the first active region 105a, and the second active structure may include a second active region 105b, and second sacrificial layers and second channel layers alternately stacked on the and the second active region 105b. The first active region 105a and the second active region 105b may have different conductivity types. In an example embodiment, the first active region 105a may have an N-type conductivity and the second active region 105b may have a P-type conductivity.

In a region in which a portion of the substrate 101 is removed, the field regions 107 may be formed by filling an insulating material, and then partially removing the insulating material such that the active regions 105 protrude. The field regions 107 may be formed to cover a portion of side surfaces of the active regions 105. Upper surfaces of the field regions 107 may be formed to be lower than upper surfaces of the active regions 105. The field regions 107 may include silicon oxide. The field regions 107 may include first to third field regions 107a, 107b, and 107c isolated by the first and second active regions 105a and 105b, and the second field region 107b may be disposed between the first and second active regions 105a and 105b.

A preliminary sacrificial gate layer SGL′ may be formed on the substrate 101 to cover the active structures 105, 118, and 140 and the field regions 107. The preliminary sacrificial gate layer SGL′ may have an upper surface having a level the same as or higher than an upper surface of an uppermost channel layer 140 among the channel layers 140. The preliminary sacrificial gate layer SGL′ may include a semiconductor material, for example, polycrystalline silicon.

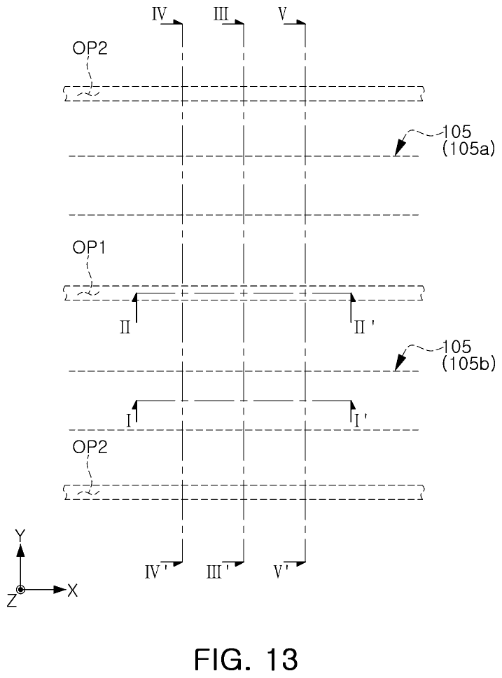

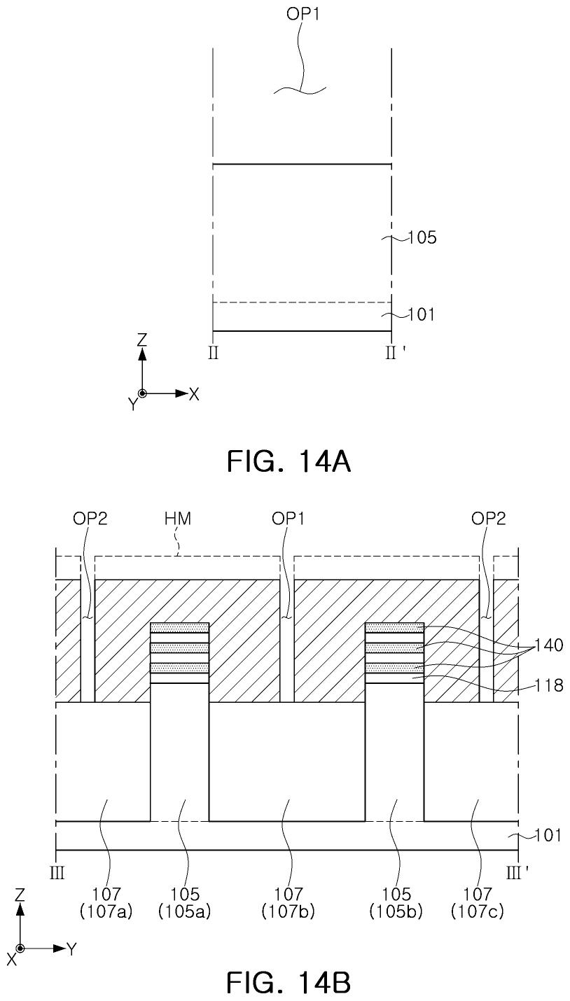

Referring to FIGS. 13, 14A, and 14B, openings OP1 and OP2 passing through the preliminary sacrificial gate layer SGL′ may be formed using a mask HM.

The openings OP1 and OP2 exposing portions of the upper surfaces of the field regions 107 may be formed by performing an exposure process and an etching process using the mask HM. The exposure process may include, for example, extreme ultraviolet lithography (EUV) using a light source having an extreme ultraviolet wavelength. The mask HM may include a plurality of layers.

In an example embodiment, lower ends of the openings OP1 and OP2 may be substantially the same as the upper surfaces of the field regions 107. In some example embodiments, the openings OP1 and OP2 may extend into the field regions 107, and the field regions 107 may be partially recessed.

The openings OP1 and OP2 may have a trench shape extending parallel to each other in the X-direction, but may also have a hole shape in some example embodiments.

In an example embodiment, the openings OP1 and OP2 include a first opening OP1 on the second field region 107b and second openings OP2 on the first field region 107a and the third field region 107c.

In the present operation, the semiconductor device 100a of FIG. 3 may be provided by forming the openings OP1 and OP2 to have a relatively wide width.

In the present operation, the first opening OP1 may be formed to be biased in a direction between the first and second active regions 105a and 105b depending on an alignment state of the mask HM or process conditions of the exposure and etching processes, and accordingly the semiconductor device 100c of FIG. 5 may be provided.

In the present operation, the semiconductor device 100g of FIG. 9 may be provided by forming hole-shaped openings together with trench-shaped openings.

Referring to FIGS. 15A and 15B, the semiconductor liners 115 may be formed to cover sidewalls of the openings OP1 and OP2, and an insulating material may be filled in the openings OP1 and OP2 to form preliminary insulating structures 120′ and 130′.

A deposition process may be performed to conformally form a semiconductor material on the sidewalls and bottom surfaces of the openings OP1 and OP2 and an upper surface of the preliminary sacrificial gate layer SGL′, and an etching process may be performed to remove the semiconductor material disposed on the upper surface of the preliminary sacrificial gate layer SGL′ and the bottom surfaces of the openings OP1 and OP2, thereby forming the semiconductor lines 115. The semiconductor liners 115 may include, for example, silicon germanium (SiGe). A thickness of each of the semiconductor liners 115 may be in a range of about 1 nm to about 10 nm. In some example embodiments, a process of forming the semiconductor liners 115 may be omitted.

In the present operation, when the process of forming the semiconductor liners 115 is omitted, the semiconductor device 100 of FIGS. 2A to 2E may be formed. When a subsequent process is performed after the semiconductor liners 115 are formed, the semiconductor device 100e of FIGS. 7A and 7B may be formed.

Subsequently, an insulating material may be filled in the openings OP1 and OP2, and a planarization process may be performed to remove the insulating material on the upper surface of the preliminary sacrificial gate layer SGL′, thereby forming preliminary insulating structures 120′ and 130′. The insulating material may include a nitride-based material, for example, at least one of SiN, SiON, SiCN, or SiOCN.

The preliminary insulating structures 120′ and 130′ may include a first preliminary insulating structure 120′ in the first opening OP1 and second preliminary insulating structures 130′ in the second openings OP2′. The first and second preliminary insulating structures 120′ and 130′ may be simultaneously formed in the present operation, and thus may include the same insulating material.

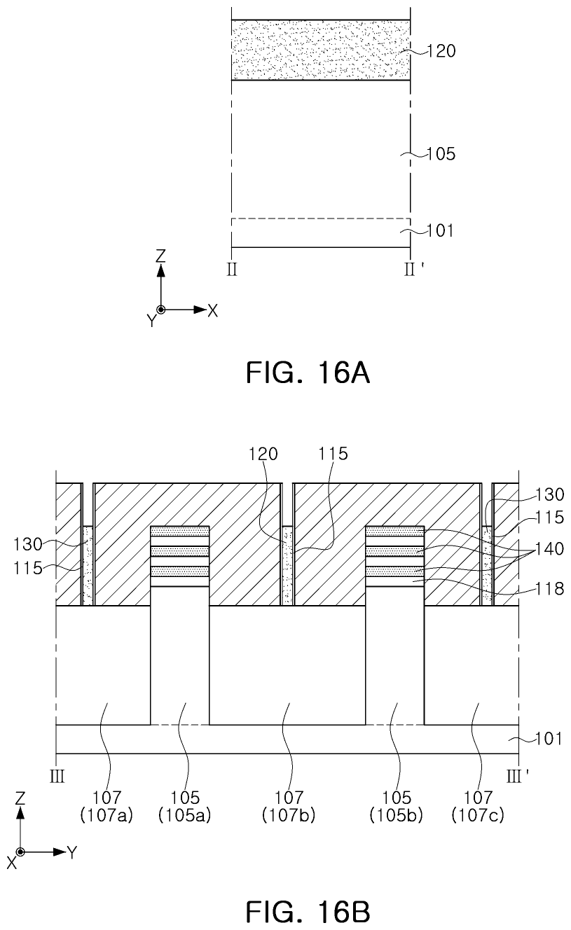

Referring to FIGS. 16A and 16B, the first and second preliminary insulating structures 120′ and 130′ may be partially removed to form the first and second insulating structures 120 and 130.

An etch-back process of selectively removing the first and second preliminary insulating structures 120′ and 130′ may be performed, which is removing a portion of the insulating structures 120′ and 130′ respect to the semiconductor liners 115 and the preliminary sacrificial gate layer SGL′, thereby forming the first and second insulating structures 120 and 130.

In an example embodiment, the upper surfaces of the first and second insulating structures 120 and 130 may be adjusted to be the same as or similar to the upper surface of the uppermost channel layer 140 through the etch-back process. Accordingly, levels of the upper surfaces of the first and second insulating structures 120 and 130 may be changed in various manners.

In the present operation, the levels of the upper surfaces of the first and second insulating structures 120 and 130 may be formed to be relatively high by adjusting process conditions of the etch-back process, and accordingly the semiconductor device 100b of FIG. 4 may be provided.

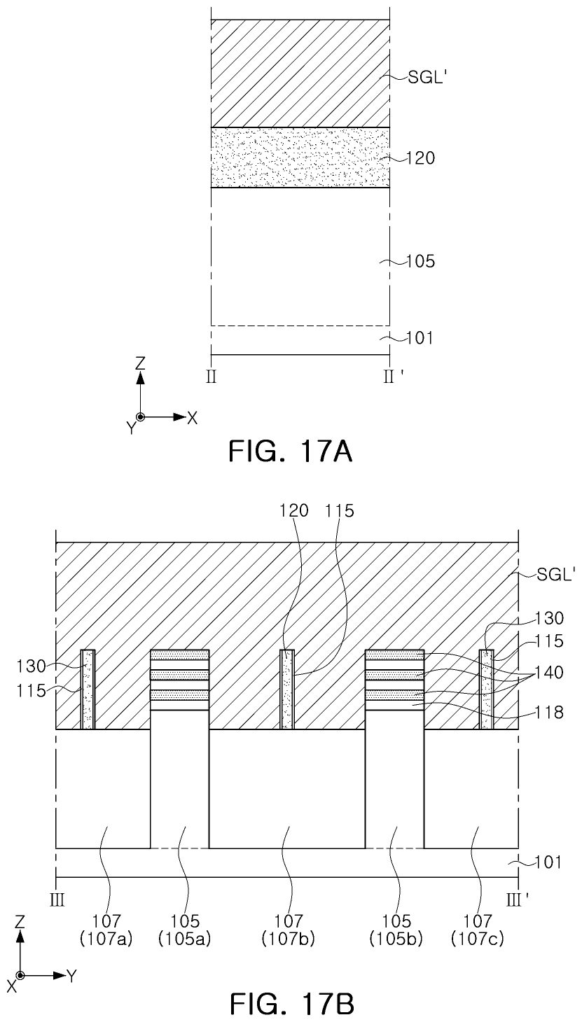

Referring to FIGS. 17A and 17B, the preliminary sacrificial gate layer SGL′ may be additionally formed.

After a planarization process of removing a portion of the preliminary sacrificial gate layer SGL′ and a portion of the semiconductor liners 115 is performed, the preliminary sacrificial gate layer SGL′ may be additionally formed. Accordingly, the upper surfaces of the first and second insulating structures 120 and 130 may be covered by the preliminary sacrificial gate layer SGL′. In some example embodiments, the preliminary sacrificial gate layer SGL′ may be formed without performing the planarization process.

Referring to FIGS. 18, 19A, 19B, 19C, and 19D, the sacrificial gate structure SG may be formed.

After an insulating material is deposited on the preliminary sacrificial gate layer SGL′, an etching process may be performed to form the sacrificial gate structure SG including a sacrificial gate layer SGL and a sacrificial gate capping layer SGC. The active structures 105, 111, and 140, the insulating structures 120 and 130, and the field regions 107 may be at least partially exposed by the etching process. The sacrificial gate capping layer SGC may be formed of, for example, a silicon nitride layer.

The sacrificial gate structure SG may extend above the insulating structures 120 and 130 and the active structures 105, 111, and 140 in a direction, for example, the Y-direction to intersect the insulating structures 120 and 130 and the active structures 105, 111, and 140. In an example embodiment, while the etching process is performed, the semiconductor liners 115 may be removed together. Accordingly, in a region in which the sacrificial gate structure SG and the semiconductor liners 115 overlap, tunnel portions OR corresponding to the semiconductor liners 115 may be formed. However, in some example embodiments, when the semiconductor liners 115 are omitted, the tunnel portions OR may also be omitted.

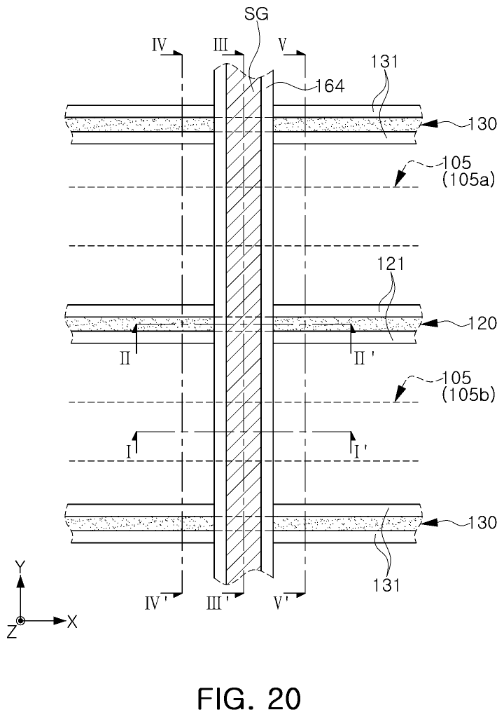

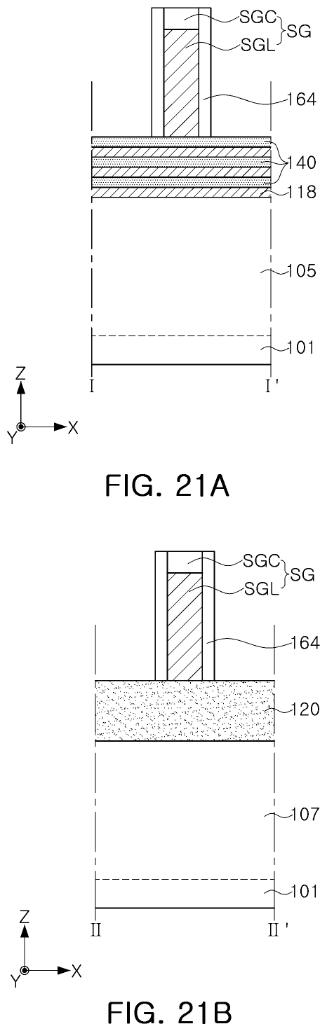

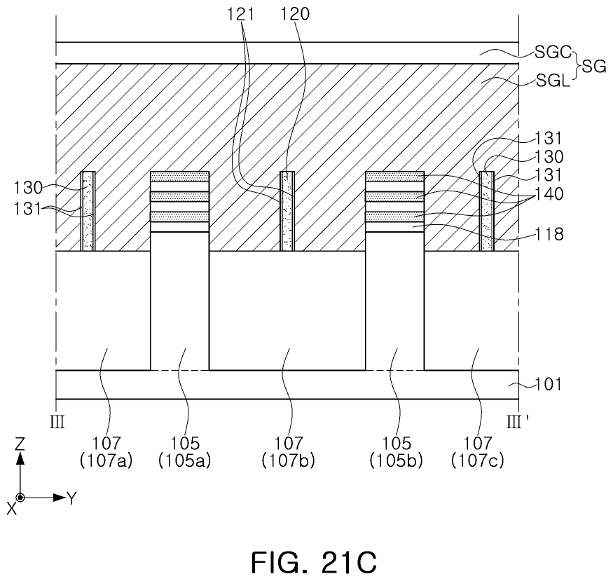

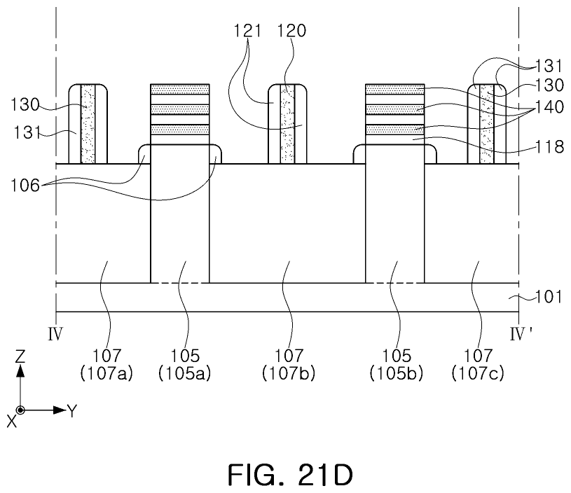

Referring to FIGS. 20, 21A, 21B, 21C, and 21D, the gate spacer 164 and the insulating liners 121 and 131 may be formed.

A deposition process using an insulating material may be performed to conformally cover the sacrificial gate structure SG and the exposed insulating structures 120 and 130. The insulating material may include a material having insulating properties, for example, at least one of SiO, SiN, SiCN, SiOC, SiON, and SiOCN. In some example embodiments, the deposition process may be performed multiple times using two or more insulating materials.

Subsequently, an anisotropic etch process may be performed to remove the insulating material on an upper surface of the sacrificial gate structure SG and the upper surfaces of the insulating structures 120 and 130, thereby forming the gate spacers 164 extending in the Y-direction on side surfaces of the sacrificial gate structure SG and the insulating liners 121 and 131 extending in the X-direction on side surfaces of the insulating structures 120 and 130.

The gate spacers 164 and the insulating liners 121 and 131 may be formed through the same process, and accordingly may have the same material and/or the same number of material layers.

In an example embodiment, the insulating structures 120 and 130 may include the first portions 120_P1 and 130_P1 overlapping the sacrificial gate structure SG and the remaining second portions 120_P2 and 130_P2.

In an example embodiment, the insulating material may be filled in the tunnel portions OR while the deposition process is performed. Accordingly, the insulating liners 121 and 131 may have a thickness the same as or similar to those of the gate spacers 164 on side surfaces of the second portions 120_P2 and 130_P2, and may have a thickness the same as or similar to those of the tunnel portions OR or the semiconductor liners 115 on side surfaces of the first portions 120_P1 and 130_P1. Accordingly, the insulating liners 121 and 131 may have different thicknesses on the first portions 120_P1 and 130_P1 and on the second portions 120_P2 and 130_P2. In this case, the semiconductor device 100e of FIGS. 7A to 7B may be provided through a subsequent process.

However, in some example embodiments, when the semiconductor liners 115 or the tunnel portions OR are omitted, the insulating liners 121 and 131 may be disposed only on the side surfaces of the second portions 120_P2 and 130_P2, and may not be disposed on the side surfaces of the first portions 120_P1 and 130_P1. Accordingly, the insulating liners 121 and 131 may have a line shape intermittently extending in the X-direction on the side surfaces of the insulating structures 120 and 130. In this case, the semiconductor device 100 of FIGS. 1 to 2E may be provided through a subsequent process.

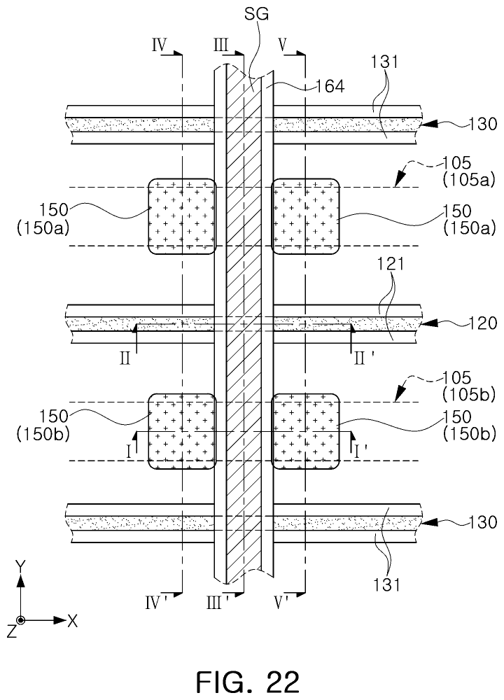

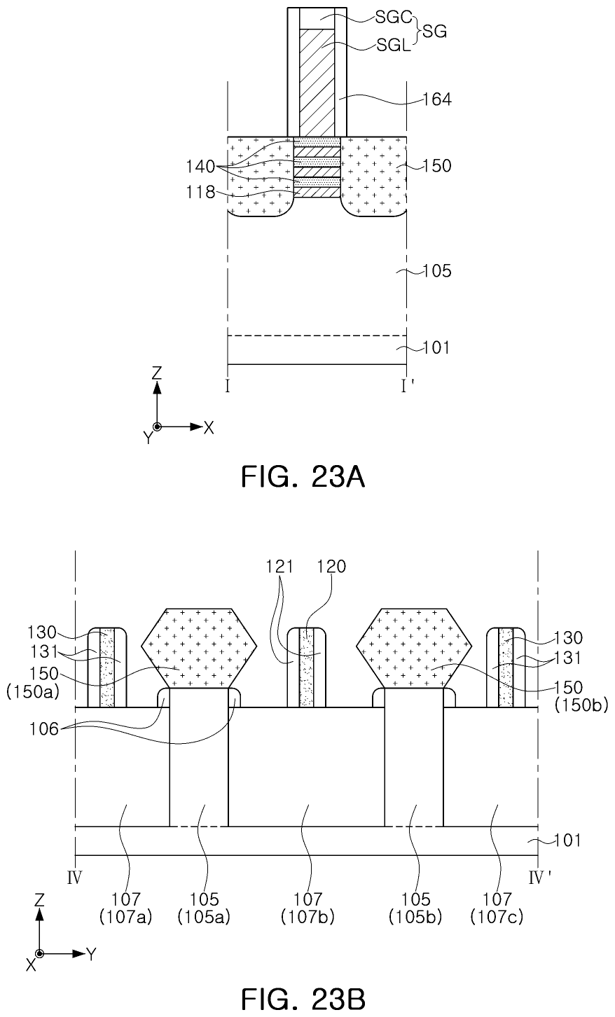

Referring to FIGS. 22, 23A, and 23B, the source/drain regions 150 may be formed.

The exposed sacrificial layers 118 and channel layers 140 may be removed from at least one side of the sacrificial gate structure SG to form a recess portion and expose the active regions 105. A portion of the substrate 101 may be recessed by forming the recess portion to have a high depth, but the present disclosure is not limited thereto, and the recess portion may be recessed such that a lower surface of the recess portion is in contact with the substrate 101.

In the present operation, a portion of the sacrificial layers 118 exposed by the recess portion may be further removed. The sacrificial layers 118 exposed by the recess portion may be selectively etched with respect to the channel layers 140 by, for example, a wet etching process to partially remove from side surfaces in the X-direction.

In an example embodiment, inner spacer layers may be formed in a region in which a portion of the side surfaces of the sacrificial layers 118 is removed. The inner spacer layers may include at least one of SiN, SiCN, SiOCN, SiBCN, and SiBN. The inner spacer layers may be formed of a material the same as that the gate spacer 164, but the present disclosure is not limited thereto. However, in some example embodiments, an operation of removing a portion of the sacrificial layers 118 and forming the inner spacer layers may be omitted.

Subsequently, on at least one side of the sacrificial gate structure SG and the gate spacer 164, the source/drain regions 150 may be formed on the active regions 105. The source/drain regions 150 may be formed by performing an epitaxial growth process in the recess portion. The source/drain regions 150 may include impurities by, for example, in-situ doping. In an example embodiment, the source/drain regions 150 may include the first source/drain regions 150a formed on the first active region 105a and the second source/drain regions 150b formed on the second active region 105b.

Subsequently, referring to FIGS. 1 to 2E, an insulating material may be filled to cover the sacrificial gate structure SG, the gate spacer 164, the source and drain regions 150, the field regions 107, and the insulating structures 120 and 130, and a planarization process may be performed, thereby forming the interlayer insulating layer 190.

Subsequently, the gate structure 160 may be formed by removing the sacrificial gate structure SG and forming the gate dielectric layer 162, the gate electrode 165, and the gate capping layer 166. In addition, the gate isolation patterns 135 extending in the X-direction may be formed on the second insulating structures 130. The gate isolation patterns 135 may include a portion in contact with the upper surfaces of the second insulating structures 130, the portion overlapping the second insulating structures 130 in the Z-direction. An aspect ratio of openings for forming the gate isolation patterns 135 may be relatively lowed by the second insulating structures 130 disposed on the field regions 107. Accordingly, a process difficulty level of a process of forming the gate isolation patterns 135 may be improved. An order of forming the gate structure 160 and the gate isolation pattern 135 may be changed in various manners in some example embodiments.

Contact holes passing through the interlayer insulating layer 190 to expose a portion of the source/drain regions 150a and 150b may be formed, and a conductive material may be filled therein to form the first and second contact plugs 171 and 172 and the common contact plug 173. A partially recessed lower end of a contact hole for forming the common contact plug 173 may be improved by the first insulating structure 120 on the field regions 107. The first insulating structure 120 may prevent a portion of the lower end of the contact hole not overlapping the source/drain regions 150 from being recessed due to a difference in etching rate between the source/drain regions 150 and the interlayer insulating layer 190.

While example embodiments have been shown and described above, it will be apparent to those skilled in the art that modifications and variations could be made without departing from the scope of the present disclosure as defined by the appended claims.

As described above, a semiconductor device may include insulating structures extending parallel to active regions on field regions to prevent leakage current between adjacent source/drain regions, a tilt phenomenon of a gate structure, or common contact plug recess defects, and thus may have improved yield.

The various and beneficial advantages and effects of example embodiments are not limited to the above description, and will be more easily understood in the course of describing specific example embodiments.

Herein, a lower side, a lower portion, a lower surface, and the like, are used to refer to a direction toward a substrate in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an intermediate layer as well as a direct connection between two components with or without intervening layers or components. In addition, “electrically connected” conceptually includes a physical connection and a physical disconnection. It can be understood that when an element is referred to with terms such as “first” and “second”, the element is not limited thereby. They may be used only for a purpose of distinguishing an element from the other elements, and may not limit the sequence or importance of the elements. In some cases, a first element may be referred to as a second element without departing from the scope of the claims set forth herein. Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only in order to describe an example embodiment rather than limiting the present disclosure. In this case, singular forms include plural forms unless interpreted otherwise in context.

What is claimed is:

1. A semiconductor device comprising:
active regions including a first active region and a second active region parallel to each other and respectively extending on a substrate in a first horizontal direction;
a field region defining the active regions on the substrate;
a first insulating structure extending in the first horizontal direction on the field region between the first active region and the second active region;
a gate structure extending, in a second horizontal direction, to intersect the active regions and the first insulating structure on the substrate;
source/drain regions disposed on at least one side of the gate structure, the source/drain regions including a first source/drain region disposed on the first active region and a second source/drain region on the second active region; and
a common contact plug disposed on a first side of the gate structure and electrically connected to the first and second source/drain regions opposing each other in the second horizontal direction,
wherein the first insulating structure includes a first portion overlapping the gate structure in a vertical direction, perpendicular to the first and second horizontal directions, and a second portion other than the first portion, and
at least a portion of the second portion of the first insulating structure overlaps the common contact plug in the vertical direction.

2. The semiconductor device of claim 1, wherein
the gate structure is in contact with at least a portion of an upper surface of the first portion of the first insulating structure,
the gate structure is in contact with at least a portion of a side surface of the first portion of the first insulating structure, and
the common contact plug is in contact with an upper surface of the second portion of the first insulating structure.

3. The semiconductor device of claim 1, wherein an upper surface of the first insulating structure is positioned on a level lower than that of an upper surface of the gate structure, relative to the substrate.

4. The semiconductor device of claim 1, further comprising:
a second insulating structure spaced apart from first insulating structure and extending parallel to the first insulating structure on the field region; and
a gate isolation pattern extending in the first horizontal direction on the second insulating structure,
wherein the gate structure includes first and second gate structures opposing each other in the second horizontal direction,
the second insulating structure and the gate isolation pattern are disposed between the first and second gate structures, and
the second insulating structure overlaps the gate isolation pattern in the vertical direction.

5. The semiconductor device of claim 4, wherein an upper surface of the gate isolation pattern is positioned on a level substantially the same as or higher than that of an upper surface of the gate structure.

6. The semiconductor device of claim 4, wherein the second insulating structure includes a material the same as that of the first insulating structure, and has an upper surface having a level substantially the same as that of an upper surface of the first insulating structure.

7. The semiconductor device of claim 4, further comprising:
a first contact plug electrically connected to the first source/drain region disposed on a second side opposing the first side of the gate structure in the first horizontal direction; and
a second contact plug electrically connected to the second source/drain region disposed on the second side of the gate structure,
wherein at least a portion of the second insulating structure overlaps the first and second contact plugs in the vertical direction.

8. The semiconductor device of claim 1, further comprising:
insulating liners extending in the first horizontal direction on side surfaces of the second portion of the first insulating structure.

9. The semiconductor device of claim 8, wherein
the gate structure includes a gate electrode extending in the second horizontal direction and gate spacers extending in the second horizontal direction on side surfaces of the gate electrode, and
the insulating liners and the gate spacers include a same material.

10. The semiconductor device of claim 9, wherein each of the insulating liners has a thickness substantially the same as that of each of the gate spacers.

11. The semiconductor device of claim 1, wherein the common contact plug is in contact with an upper surface of the first source/drain region, an upper surface of the second source/drain region, and an upper surface of the first insulating structure.

12. The semiconductor device of claim 11, wherein the common contact plug has a portion extending onto a side surface of the first insulating structure.

13. The semiconductor device of claim 1, comprising:
a plurality of channel layers disposed to be spaced apart from each other in the vertical direction on the active regions,
wherein the plurality of channel layers is at least partially in contact with the source/drain regions.

14. The semiconductor device of claim 1, wherein the first insulating structure includes at least one of SiN, SiON, SiCN, or SiOCN.

15. A semiconductor device comprising:
active regions extending on a substrate in a first horizontal direction;
a field region defining the active regions;
an insulating structure extending parallel to the active regions on the field region;
insulating liners extending on side surfaces of the insulating structure in the first horizontal direction;
a gate structure extending, in a second horizontal direction, to intersect the active regions and the insulating structure on the substrate; and
source/drain regions disposed on the active regions and on at least one side of the gate structure,
wherein the insulating structure has a first portion overlapping the gate structure in a vertical direction, perpendicular to the first and second horizontal directions, and a second portion other than the first portion, and
a first thickness of each of the insulating liners on a side surface of the first portion of the insulating structure is less than a second thickness of each of the insulating liners on a side surface of the second portion of the insulating structure.

16. The semiconductor device of claim 15, wherein
the first thickness is in a range of about 1 nanometers (nm) to about 10 nm, and
the second thickness is in a range of about 5 nm to about 30 nm.

17. The semiconductor device of claim 15, wherein
the gate structure includes a gate electrode, a gate spacer extending in the second horizontal direction on at least one side surface of the gate electrode, and a gate dielectric layer disposed between the gate electrode and the gate spacer, and
the gate spacer has a thickness substantially equal to the second thickness.

18. The semiconductor device of claim 15, wherein
the insulating structure is in contact with the insulating liners, and
the insulating structure has outer regions including germanium (Ge) adjacent to a portion in contact with the insulating liners.

19. The semiconductor device of claim 15, wherein an upper surface of the insulating structure is positioned on a level lower than that of an upper surface of the gate structure, relative to the substrate.

20. A semiconductor device comprising:
a first active region and a second active region parallel to each other and respectively extending on a substrate in a first horizontal direction;
first, second, and third field regions defining the first and second active regions and spaced apart by the first and second active regions;
a first insulating structure extending in the first horizontal direction on the second field region between the first active region and the second active region;
a second insulating structure extending parallel to the first insulating structure on the first field region or the third field region;
insulating liners extending in the first horizontal direction on side surfaces of each of the first and second insulating structures;
gate structures including first and second gate structures extending, in a second horizontal direction, to intersect the first and second active regions and the first and second insulating structures on the substrate, the first and second gate structures opposing each other in the second horizontal direction;
source/drain regions including first source/drain regions disposed on at least one side of the gate structures and disposed on the first active region and second source/drain regions disposed on the second active region;
a common contact plug electrically connected to the first source/drain regions and the second source/drain regions; and
a gate isolation pattern disposed between the first and second gate structures on the second insulating structure,
wherein each of the gate structures includes a gate electrode extending in the second horizontal direction and a gate spacer disposed on at least one side surface of the gate electrode, and
the insulating liners and the gate spacer include a same material.
